(19) United States
(12) Patent Application Publication
(10) Pub. No.: US 2026/0204997 A1
(43) Pub. Date: Jul. 16, 2026

(54) CALIBRATION SYSTEMS AND METHODS FOR POWER MANAGEMENT SYSTEMS

(71) Applicant: Qorvo US, Inc., Greensboro, NC (US)

(72) Inventors: Baker Scott, San Jose, CA (US); George Maxim, Saratoga, CA (US)

(21) Appl. No.: 19/133,127

(22) PCT Filed: Nov. 27, 2023
(86) PCT No.: PCT/US2023/081086

§ 371 Date: May 27, 2025

Related U.S. Application Data
(60) Provisional application No. 63/386,955, filed on Dec. 12, 2022.

(51) Int. Cl. H02M 1/00; G01R 27/16; H02M 3/00

(52) U.S. Cl. CPC H02M 1/0003; G01R 27/16; H02M 3/003

(57) ABSTRACT

Calibration systems and methods for power management systems are disclosed. In one aspect, a power management circuit may include a direct current (DC) to DC converter that operates with external surface-mounted components provided by third parties. Exemplary aspects of the present disclosure provide systems and methods to measure the inductance, capacitance, and effective impedance of these external components. Based on the measurements, adjustments to a feedback loop may be made to provide desired operation. In a specific aspect, switches may be used along with an injected current to measure inductance, capacitance, and impedance independently (orthogonally). By providing the flexibility to interoperate with components from different vendors or components that may have loose design tolerances, greater flexibility is provided to original equipment manufacturers of mobile computing devices.

### PRIORITY APPLICATION

This application claims the benefit of U.S. Provisional Patent Application Ser. No. 63/386,955, filed on Dec. 12, 2022, entitled, “CALIBRATION SYSTEMS AND METHODS FOR POWER MANAGEMENT SYSTEMS,” the disclosure of which is hereby incorporated herein by reference in its entirety.

### BACKGROUND

### I. Field of the Disclosure

The technology of the disclosure relates generally to calibrating control loop settings for a power management system, including a direct current (DC)-to-DC (DC-DC) converter.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been increased pressure to find ways to increase the bandwidth of wireless data exchange. Such pressure has led to the evolution of cellular standards with increasingly strict timing requirements. These timing requirements, in turn, have caused the creation of increasingly complex power management circuits, including average power tracking (APT) circuits or envelope tracking integrated circuits (ICs) (ETICs). Such power management circuits may be provided by different vendors and/or be used with other vendors. Accordingly, making sure that such power management circuits behave in a desired, expected fashion creates room for innovation.

### SUMMARY

Aspects disclosed in the detailed description include calibration systems and methods for power management systems. A power management circuit may include a direct current (DC)-to-DC (DC-DC) converter that operates with external surface-mounted components provided by third parties. Exemplary aspects of the present disclosure provide systems and methods to measure the inductance, capacitance, and effective impedance of these external components. Based on the measurements, adjustments to a feedback loop may be made to provide desired operation. In a specific aspect, switches may be used along with an injected current to measure inductance, capacitance, and impedance independently (orthogonally). By providing the flexibility to interoperate with components from different vendors or components that may have loose design tolerances, greater flexibility is provided to original equipment manufacturers of mobile computing devices.

In this regard in one aspect, a power management die is disclosed. The power management die comprises a DC-DC converter configured to output a signal for an amplifier chain at a first node. The power management die also comprises a calibration circuit. The calibration circuit comprises a current source configured to provide a known current to the first node. The calibration circuit also comprises a measurement circuit coupled to the first node configured to measure a voltage at the first node. The calibration circuit also comprises a control circuit configured to calculate values associated with an output filter and use those values to control, in part, the DC-DC converter.

In another aspect, a method of calibrating a power management die is disclosed. The method comprises providing a current having a known slope from a current source to a first node at an output of a direct current DC-DC converter. The method also comprises measuring a voltage at the first node. The method also comprises calculating values for parameters of an output filter based on the voltage.

In another aspect, a mobile communication device comprising a power management die is disclosed. The mobile communication device includes a direct current (DC)-to-DC (DC-DC) converter configured to output a signal for an amplifier chain at a first node and a calibration circuit. The calibration circuit of the mobile communication device comprising a current source configured to provide a known current to the first node, a measurement circuit coupled to the first node configured to measure a voltage at the first node, and a control circuit configured to calculate values associated with an output filter and use those values to control, in part, the DC-DC converter.

### BRIEF DESCRIPTION OF THE DRAWINGS

FIG. 1 is a block diagram of an exemplary power management system that includes a converter die in a module with external surface-mounted devices (SMDs) interoperating with the die;

FIG. 2 is a block diagram of a direct current (DC)-to-DC (DC-DC) converter within the converter die having a calibration circuit to measure off die components and adjust a feedback loop for the DC-DC converter;

FIG. 3 provides additional details about the feedback loop of FIG. 2;

FIG. 4 provides a circuit diagram of a possible switching and measurement circuit for the calibration circuit of the present disclosure;

FIG. 5 is a circuit diagram of a calibrated current source that may be used as an injection signal for the calibration circuit of the present disclosure;

FIG. 6 is a circuit diagram combining the calibrated current source with a circuit to be measured, having two possible measurement options;

FIG. 7 is a circuit diagram that expands on the circuit diagram of FIG. 6, showing switching paths as well as injected current profiles to perform the desired measurements;

FIG. 8 is a circuit diagram that expands on the circuit diagram of FIG. 6 but shows an alternate differential measuring option;

FIG. 9 is a circuit diagram that expands on the circuit diagram of FIG. 6, but includes a sampling circuit to provide compression for capacitance measurements;

FIG. 10 is a flowchart illustrating an exemplary process for calibrating a stabilization filter for a DC-DC converter; and

FIG. 11 is a block diagram of a transceiver in a mobile terminal, which may include a DC-DC converter that is calibrated according to aspects of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include calibration systems and methods for power management systems. A power management circuit may include a direct current (DC)-to-DC (DC-DC) converter that operates with external surface-mounted components provided by third parties. Exemplary aspects of the present disclosure provide systems and methods to measure the inductance, capacitance, and effective impedance of these external components. Based on the measurements, adjustments to a feedback loop may be made to provide desired operation. In a specific aspect, switches may be used along with an injected current to measure inductance, capacitance, and impedance independently (orthogonally). By providing the flexibility to interoperate with components from different vendors or components that may have loose design tolerances, greater flexibility is provided to original equipment manufacturers of mobile computing devices.

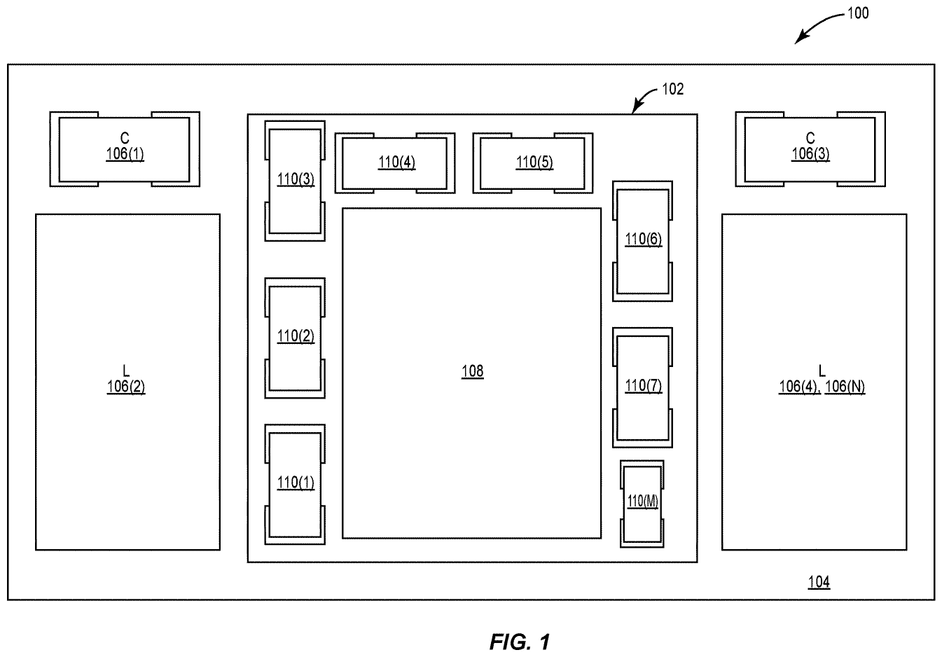

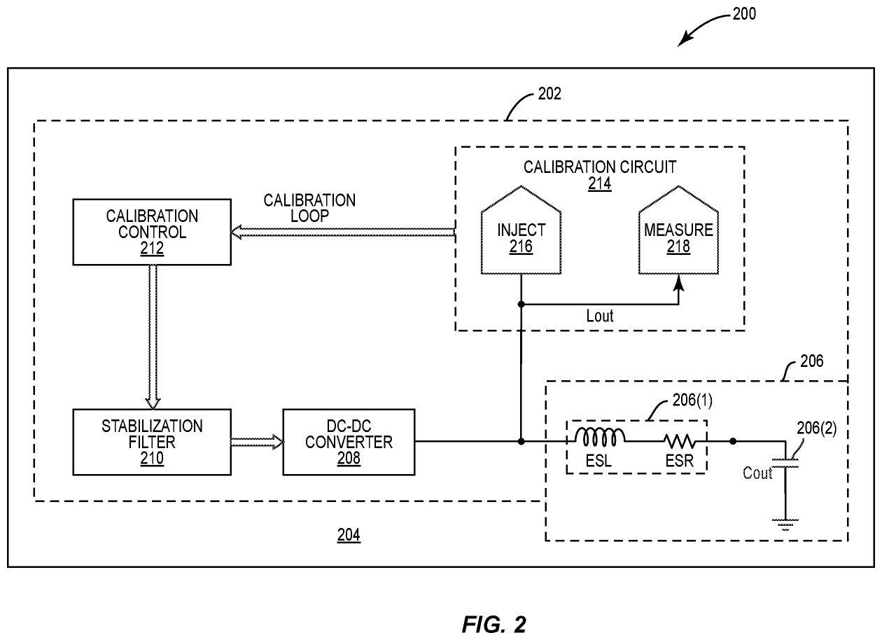

Before addressing particular aspects of the present disclosure, a bit of context is provided with reference to FIG. 1. A discussion of exemplary aspects of the present disclosure is provided below, beginning with reference to FIG. 2.

In this regard, FIG. 1 is a top plan view of a power management package 100 that may include a power management integrated circuit (PMIC) module 102 (also sometimes referred to as just a power management die) mounted on a substrate 104. The PMIC module 102 uses one or more external surface-mounted devices (SMDs) 106(1)-106(N) (where, as illustrated, N=4). The SMDs 106(1)-106(N) may be capacitors (e.g., SMD 106(1), 106(3)) or inductors (e.g., SMD 106(2), 106(4)), or the like, and, in general, are used to form output filters. In general, the SMDs 106(1)-106(N) have physical dimensions (e.g., height above the substrate 104) that exceed some design criteria for the PMIC module 102. Typically, the substrate 104 may include surface conductors or interior metal layers that act as conductors from the PMIC module 102 to the external SMDs 106(1)-106(N).

Within the PMIC module 102, a PMIC die 108 may be positioned along with internal SMDs 110(1)-110(M). The PMIC die 108 likely includes some form of average power tracking (APT) or envelope tracking (ET) circuitry that uses a DC-DC converter to generate a voltage used to control a power amplifier (PA) (not shown). A mold compound (not shown) or the like may encapsulate the PMIC die 108 and the internal SMDs 110(1)-110(M). An internal metallization layer (not shown) within the PMIC module 102 may provide electrical connections from the PMIC die 108 to the internal SMDs 110(1)-110(M). Like the external SMDs 106(1)-106(N), the internal SMDs 110(1)-110(M) may be inductors, capacitors, or the like.

In practice, a single manufacturer may make the PMIC module 102 including the PMIC die 108 and the internal SMDs 110(1)-110(M). Given the single source, the manufacturer may calibrate the PMIC die 108 to work as designed with the SMDs 110(1)-110(M). That is, any process variations or variability in inductance, impedance, or capacitance may be known to the manufacturer and appropriate correction used to provide a device that operates according to design parameters to a customer

The manufacturer of the PMIC module 102 frequently will not make the entirety of the power management package 100 and the customer of the PMIC module 102 may choose the external SMDs 106(1)-106(N). Thus, while the manufacturer of the PMIC module 102 may provide guidance as to expected values of inductance and capacitance for the external SMDs 106(1)-106(N), the manufacturer may not know a priori what sort of tolerances or variations in the inductance and capacitance values for the external SMDs 106(1)-106(N) exist. If the DC-DC converter uses current feedback based on sending an inductor voltage across an externally-mounted inductor, any change in effective series resistance (ESR) or effective series inductance (ESL) of the inductor may impact loop behavior.

Exemplary aspects of the present disclosure add a built-in self-calibration (BISC) architecture that can independently (orthogonally) measure ESR, ESL, and capacitance values of external SMDs and use such measured values to set the DC-DC converter feedback control loop variables. Orthogonal measurements allow the ESR, ESL, and capacitance values to be isolated from one another so that adjustments based on one metric do not conflict with adjustments made based on another metric. The measurements are made using an injected calibrated current having a specific profile along with switches that help isolate an element to be measured. Based on the measurements, the PMIC module stores information that is used in the feedback control loop.

In this regard, FIG. 2 shows a block diagram of the calibration architecture. Specifically, a power management package 200 may include a PMIC die 202 mounted on a substrate 204 along with one or more output filters 206 (only one shown). The output filter 206 may include an inductor 206(1) and a capacitor 206(2). The PMIC die 202 may include a DC-DC converter 208 with a stabilization filter 210. Variables within the stabilization filter 210 may be controlled by a calibration control circuit 212. The calibration control circuit 212 may learn what values to use based on signals from a calibration circuit 214. The calibration circuit 214 generally includes injection circuitry 216 to inject a measurement signal and measurement circuitry 218 to measure a response to the injected measurement signal.

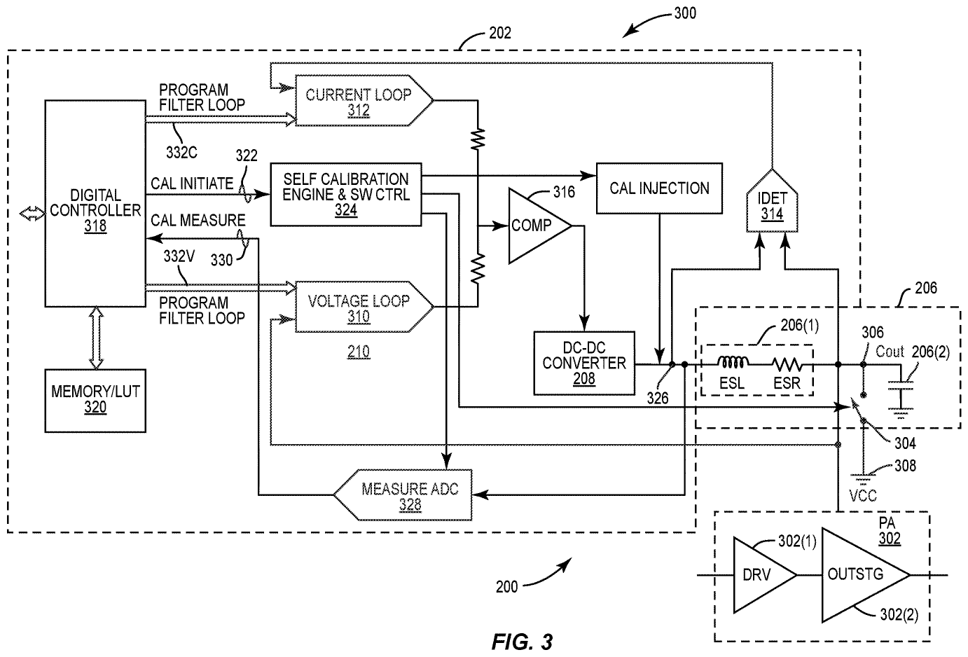

Additional details on some aspects are illustrated by system 300 in FIG. 3, which includes the power management package 200 as well as a power amplifier chain 302, which may include a driver amplifier stage 302(1) and an output amplifier stage 302(2). Other stages (not illustrated) may also be present without departing from the present disclosure. The power amplifier chain 302 is controlled to track a signal to be amplified by the power management package 200. That is, the power management package 200 controls a signal VCC which helps set the output of the power amplifier chain 302. VCC may be designed to be an APT or ET control as is understood.

The output filter 206 includes a switch 304 that selectively couples a node 306 to ground 308 when the switch 304 is closed.

The DC-DC converter 208 may have a calibration state to facilitate calibration according to aspects of the present disclosure. Specifically, when calibration is being performed, the DC-DC converter 208 may be turned off such that no signal passes from the DC-DC converter 208 to the output filter 206 and VCC is zero.

The stabilization filter 210 may be or include a feedback loop, which may be a voltage loop 310 or a current loop 312, or both. More specifically, a voltage such as VCC may be measured by the voltage loop 310, filtered, and used to adjust the DC-DC converter 208. Alternatively, a current across the output filter 206 may be measured by a current detector 314 and used by the current loop 312 to adjust the DC-DC converter 208. Where both the voltage loop 310 and the current loop 312 are present, they may be combined through a comparator 316 to adjust the DC-DC converter 208. Such feedback loops are known and not central to the present disclosure except to the extent the present disclosure teaches techniques to adjust these loops based on the calibration of the present disclosure.

In this regard, the stabilization filter 210, and more specifically the voltage loop 310 and/or the current loop 312, may be controlled by a control circuit 318 that operates with a memory 320. The memory 320 may include a look-up table (LUT) or the like to assist in implementing the present disclosure. The control circuit 318 may also initiate a calibration process with a signal 322 that causes a calibration engine and software 324 to execute the calibration process. Specifically, the calibration engine and software 324 causes a known signal to be injected at a node 326 between the DC-DC converter 208 and the output filter 206. Since the DC-DC converter 208 is turned off during calibration, this injected signal should be the only signal passing through the output filter 206. A measurement circuit 328, which may, for example, be an analog-to-digital converter (ADC), may provide a measurement signal 330 corresponding to a measurement at the node 326 to the control circuit 318. Based on this measurement, the control circuit 318 may calculate an adjustment to the stabilization filter 210 and send program signals 332C, 332V to the current loop 312 and the voltage loop 310 to make such adjustments. These adjustments may be provided based on the control circuit 318 comparing the measurements to output values in the LUT of the memory 320.

Note that while the control circuit 318 is contemplated as being a digital circuit that receives a digital signal from the ADC measurement circuit 328, it should be appreciated that the output filter 206 may be digital or analog. If the output filter 206 is digital, then the measurement circuit 328 may omit the ADC.

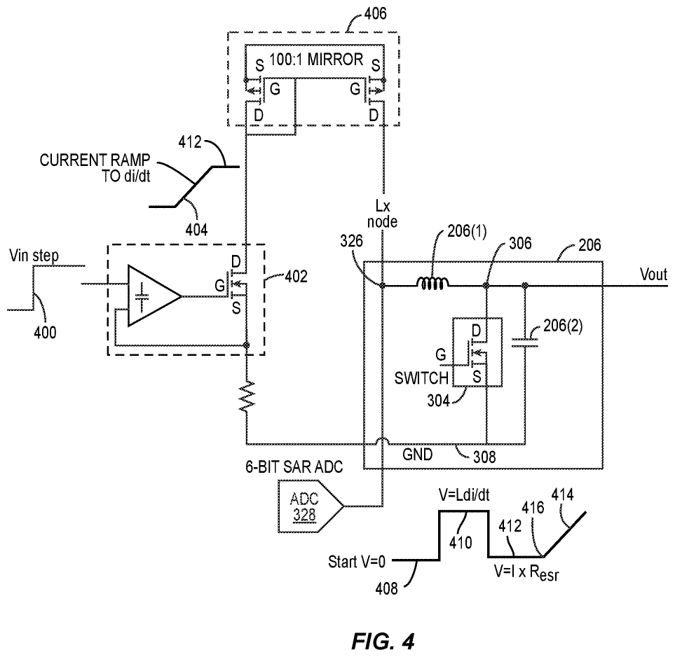

FIG. 4 provides a circuit diagram showing an exemplary aspect of the injection and measurement. In particular, the output filter 206 may include the switch 304, which may, for example, be a field effect transistor (FET) that couples the node 306 to ground 308. The switch 304 is in parallel with the capacitor 206(2) between the node 306 and the ground 308. The switch 304 also couples one end of the inductor 206(1) to the ground 308. The injection signal is injected at the node 326. Likewise, the measurement circuit 328 is coupled to the node 326. In an exemplary aspect, the injection signal begins as a voltage step signal 400 provided to a converter 402 that converts the voltage step signal 400 into a current ramp 404. The current ramp 404 is mirrored in a current mirror 406, which may, for example, be a 100:1 mirror. The output of the current mirror 406 is effectively a current source and provides a known current to the node 326.

The node 326 starts at a zero-voltage potential (408) and the switch 304 is closed to ground 308. The voltage measured by the measurement circuit 328 at the node 326 is equal to the inductance L of the inductor 206(1) multiplied by di/dt.

$$V = L \frac{di}{dt} \qquad EQ . 1$$

Since di/dt is the mirrored current ramp 404 (i.e., known) and V (410) is measured, it is possible to solve for L. When di/dt=0 corresponding to the flat portion 412 of the current ramp 404, the voltage at the node 326 is constant. Again, I is known and V (412) is measured, allowing the equation:

$$V = IR \qquad EQ . 2$$

to be solved for R, corresponding to the ESR of the inductor 206(1). The switch 304 is then opened, creating an open circuit thereacross, and changing the voltage at the node 326 to a function of C. Specifically:

$$V = \int \frac{I}{C} \qquad EQ . 3$$

The voltage is measured, and I is known, so C may be calculated. Note that it may be appropriate to begin measuring the slope 414 sometime after the corner 416 so that the slope 414 has time to settle after the switch 304 opens.

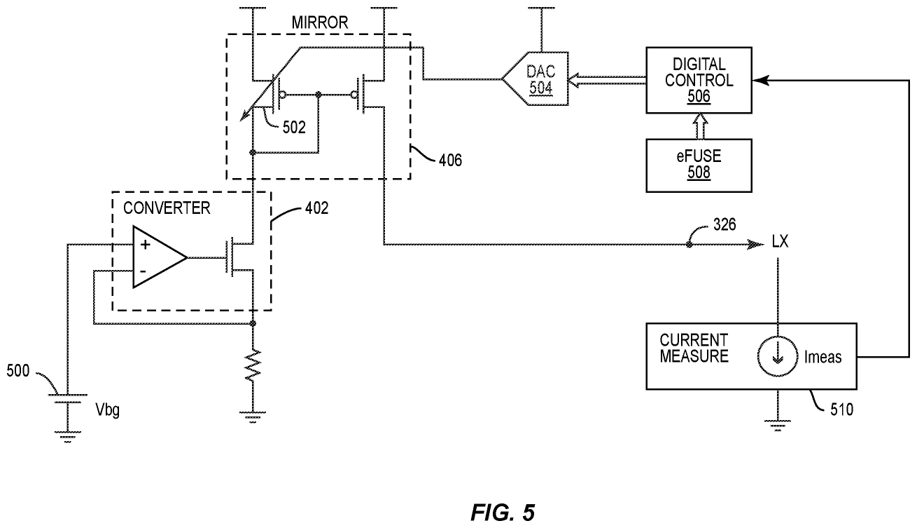

For equations 1-3 to work, I and di/dt must be known. So, a well-controlled current source may be appropriate. FIG. 5 illustrates a calibration circuit to get such a well-controlled current source.

In this regard, the voltage step signal 400 may be generated by a bandgap voltage source 500. The current mirror 406 may include an adjustable FET 502 that is controlled by a digital-to-analog converter (DAC) 504. The DAC 504 is controlled by a control circuit 506 having a memory 508. During calibration of the injection signal, a current measurement circuit 510 (which may be a probe from an external monitoring device) may provide a current measurement at the node 326 and report the current measurement to the control circuit 506. The control circuit 506 adjusts the value in the DAC 504 (e.g., sweeping across the possible values of the DAC 504) and thus adjusts the FET 502 until a desired steady current is generated. The setting for the DAC 504 is then stored in the memory 508, which may, for example, be an eFuse or the like.

After calibration of the injection signal, the current measurement circuit 510 may be removed or shut down, and calibration of the external SMDs may begin.

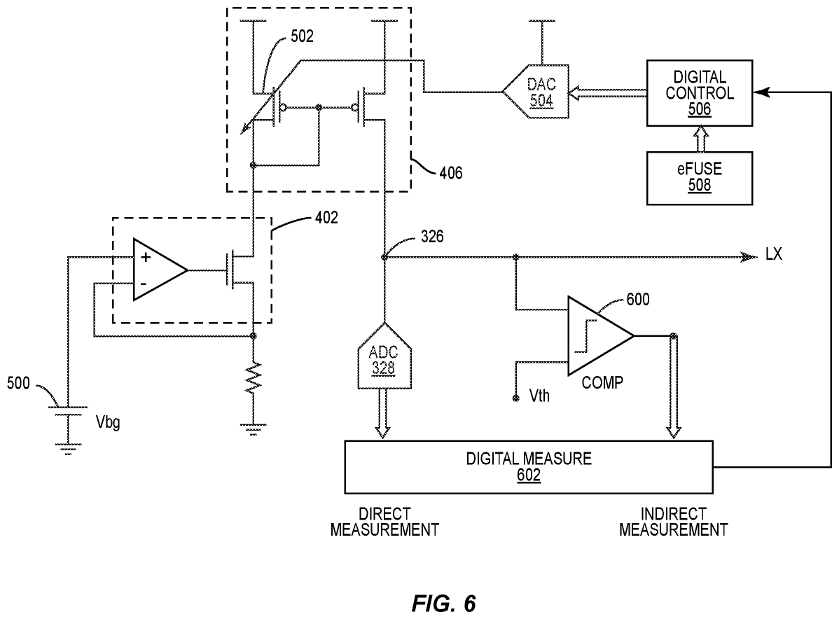

FIG. 6 provides some additional information about how measuring the injected signal may occur. Specifically, as discussed above, there may be direct measurement with an ADC of the measurement circuit 328. Further, an indirect measurement may occur, where a comparator 600 compares a measured voltage at the node 326 to a threshold voltage Vth. When the measured voltage exceeds the threshold voltage Vth, a signal is provided to a measurement circuit 602 and then to the control circuit 506.

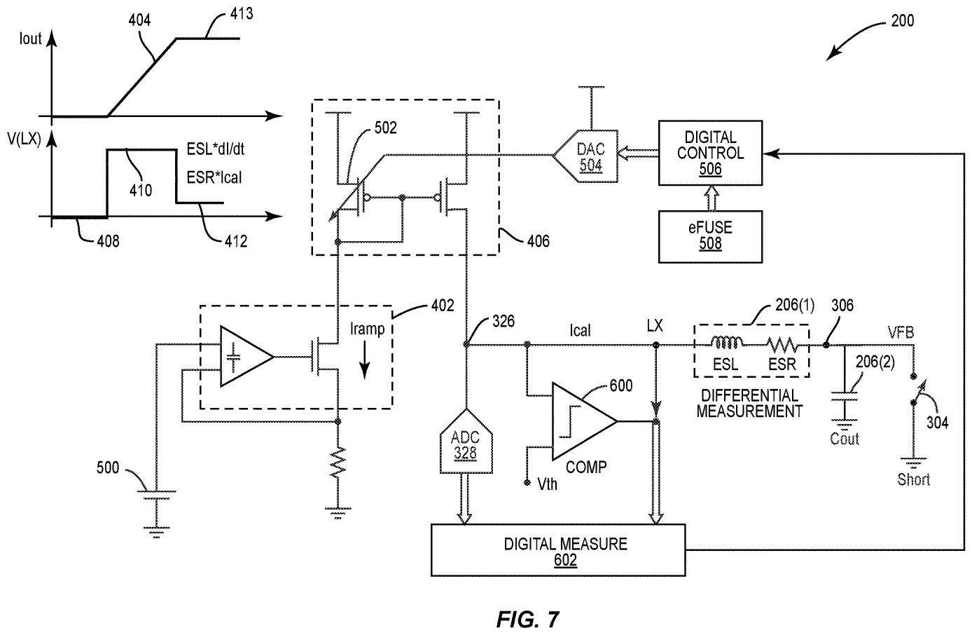

FIG. 7 is a more complete circuit diagram of the power management package 200 for more ready visualization of how the various subparts fit within the power management package 200.

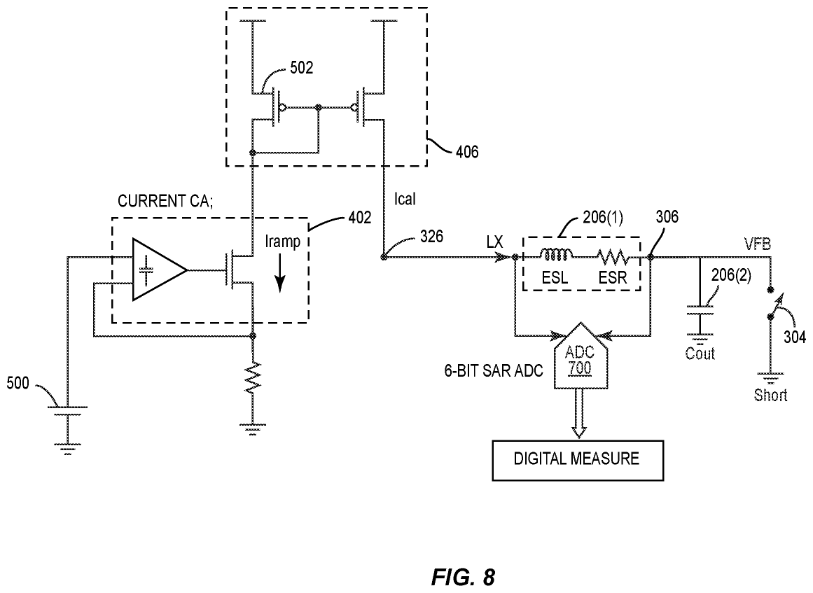

While the above discussion contemplates that the measurement is a single-ended measurement, it should be appreciated that a differential measurement may be done by measuring at both node 326 and node 306 with a measurement circuit 700, as illustrated in FIG. 8. The measurement circuit 700 may still be an ADC but contemplates a differential measurement. The differential measurement may avoid inadvertent measurement of the resistance of the switch 304.

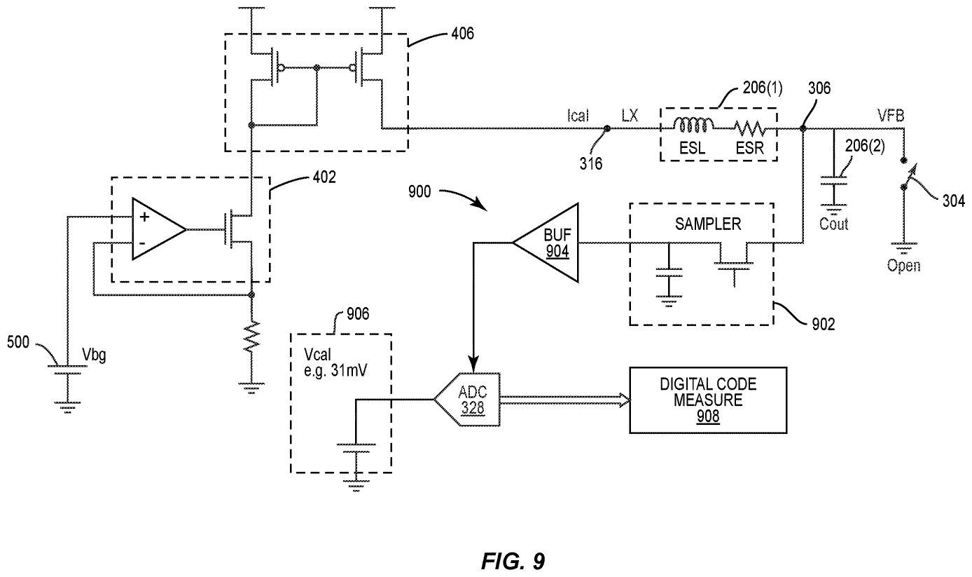

It should further be appreciated that measuring the capacitance may result in measured values that spread across multiple orders of magnitude. This poses challenges in discriminating relevant values at the low end. One way to address this spread would be through a compression circuit. A 1/X compression model is contemplated, but there are others that may be used without departing from the present disclosure. An exemplary circuit that can provide this compression is illustrated in FIG. 9, with the understanding that other circuits may be used.

In this regard, FIG. 9 illustrates a compression circuit 900 associated with the power management package 200. The compression circuit 900 includes a sampler circuit 902 that samples values at the node 306. These sampled values are buffered in a buffer 904 and provide a reference voltage (Vref) to the measurement circuit 328. The measurement circuit 328 may also receive a calibrated voltage from a voltage source 906 to create a digital code 908 indicative of the measurement.

Note that while only a single calibration circuit is shown in the above discussion, it should be appreciated that where there are multiple output filters, it may be possible to use multiple calibration circuits, one for each output filter. Likewise, while it has been contemplated that the output filters are a single inductor and a single capacitor, it should be appreciated that the principles of the present disclosure are applicable to other filter structures.

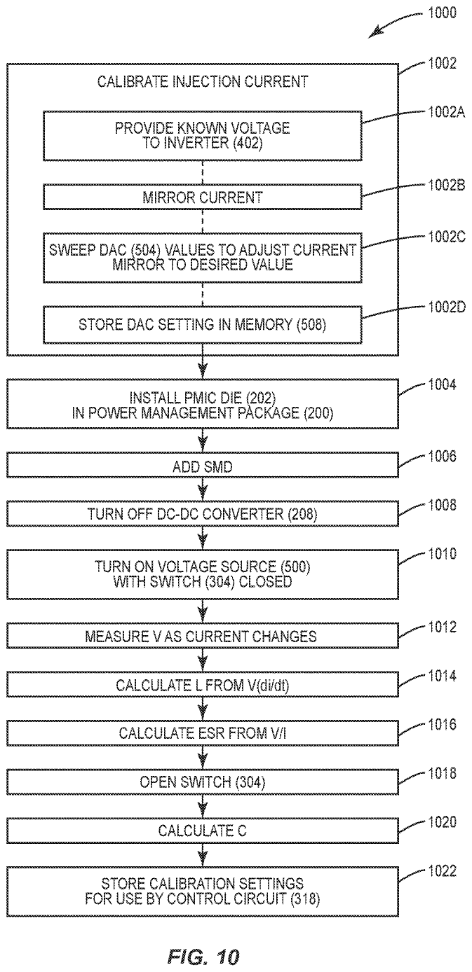

The overall process of calibration is illustrated as process 1000 in FIG. 10. In this regard, the process 1000 begins by calibrating the injection current (block 1002) by providing a known voltage to a converter 402 (block 1002A); mirroring the current (block 1002B) with the current mirror 406; sweeping the DAC 504 values to adjust the current mirror 406 to a desired value (block 1002C); and storing the DAC setting in memory 508 (block 1002D).

After the calibration of the current, the PMIC die 202 is installed in the power management package 200 (block 1004). The SMD elements are added (block 1006). The DC-DC converter 208 is turned off (block 1008). The voltage source 500 is turned on while the switch 304 is closed (block 1010).

The current will have a known slope, and the measurement circuit 328 can measure the voltage as the current changes (block 1012). The control circuit 318 may calculate L from EQ. 1 (block 1014). When the current stops changing after having reached the steady state voltage, the control circuit 318 may calculate an ESR from EQ. 2 (block 1016). The switch 304 is then opened (block 1018) and C may be calculated (block 1020) from the measured voltage. The control circuit 318 may then store the calibration settings in memory 320 for use with the feedback loop(s) 310, 312 (block 1022).

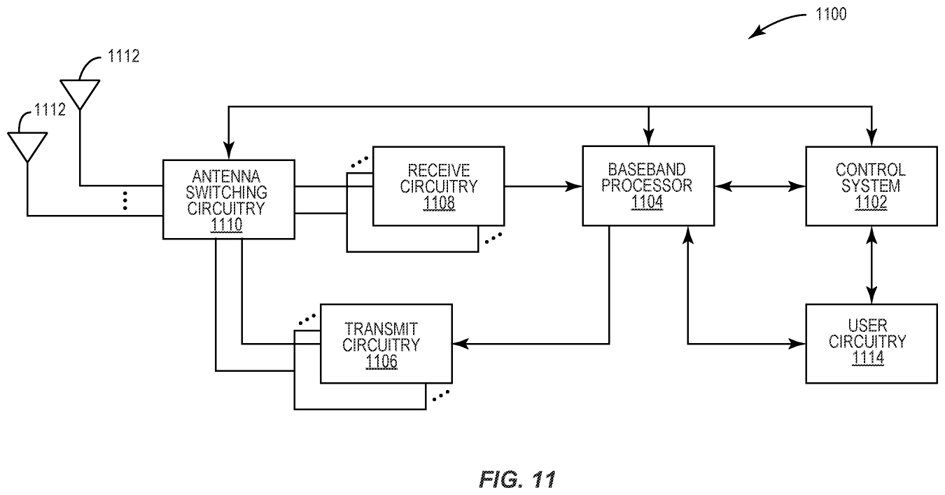

With reference to FIG. 11, the concepts described above may be implemented in various types of user elements 1100, such as mobile terminals, smart watches, tablets, computers, navigation devices, access points, and like wireless communication devices that support wireless communications, such as cellular, wireless local area network (WLAN), Bluetooth, and near field communications. The user elements 1100 will generally include a control system 1102, a baseband processor 1104, transmit circuitry 1106, receive circuitry 1108, antenna switching circuitry 1110, multiple antennas 1112, and user interface circuitry 1114. In a non-limiting example, the control system 1102 can be a field-programmable gate array (FPGA) or an application-specific integrated circuit (ASIC), as an example. In this regard, the control system 1102 can include at least a microprocessor(s), an embedded memory circuit(s), and a communication bus interface(s). The receive circuitry 1108 receives radio frequency signals via the antennas 1112 and through the antenna switching circuitry 1110 from one or more base stations. A low noise amplifier and a filter of the receive circuitry 1108 cooperate to amplify and remove broadband interference from the received signal for processing. Downconversion and digitization circuitry (not shown) will then downconvert the filtered, received signal to an intermediate or baseband frequency signal, which is then digitized into one or more digital streams using an ADC(s).

The baseband processor 1104 processes the digitized received signal to extract the information or data bits conveyed in the received signal. This processing typically comprises demodulation, decoding, and error correction operations, as will be discussed on greater detail below. The baseband processor 1104 is generally implemented in one or more digital signal processors (DSPs) and ASICs.

For transmission, the baseband processor 1104 receives digitized data, which may represent voice, data, or control information, from the control system 1102, which it encodes for transmission. The encoded data is output to the transmit circuitry 1106, where a DAC converts the digitally-encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 1112 through the antenna switching circuitry 1110. The multiple antennas 1112 and the replicated transmit and receive circuitries 1106, 1108 may provide spatial diversity. Modulation and processing details will be understood by those skilled in the art.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

1. A power management die comprising:
a direct current (DC)-to-DC (DC-DC) converter configured to output a signal for an amplifier chain at a first node corresponding to an input of an output filter;
a control circuit configured to initiate a calibration process and turn off the DC-DC converter during the calibration process; and
a calibration circuit comprising:
a current source configured to provide a known current to the first node during the calibration process;
a measurement circuit coupled to the first node configured to measure a voltage at the first node during the calibration process; and
a control circuit configured to calculate values associated with the output filter and use those values to control, in part, the DC-DC converter.

2. The power management die of claim 1, wherein the control circuit is configured to calculate an effective series inductance of an inductor in the output filter.

3. The power management die of claim 1, wherein the control circuit is configured to calculate an effective series resistance of an inductor in the output filter.

4. The power management die of claim 1, wherein the control circuit is configured to calculate a capacitance of a capacitor in the output filter.

5. The power management die of claim 1, wherein the current source comprises a current mirror coupled to a bandgap voltage source.

6. The power management die of claim 1, wherein the measurement circuit comprises an analog-to-digital converter (ADC).

7. The power management die of claim 1, wherein the control circuit is configured to control a feedback loop of the DC-DC converter.

8. The power management die of claim 1, wherein the DC-DC converter comprises an average power tracking (APT) circuit.

9. The power management die of claim 1, wherein the DC-DC converter comprises an envelope tracking circuit.

10. The power management die of claim 1, further comprising a switch selectively coupling the first node to ground.

11. The power management die of claim 10, wherein the measurement circuit is configured to measure a first value when the switch is closed and a second value when the switch is open.

12-13. (canceled)

14. The power management die of claim 1, wherein the current source is configured to provide a current having a known slope.

15. The power management die of claim 14, wherein the current source is further configured to provide a constant current after providing the current having the known slope.

16. (canceled)

17. A method of calibrating a power management die, comprising:
during a calibration process in which a direct current-to-direct current, DC-DC, converter is turned off, providing a current having a known slope from a current source to a first node corresponding to an input of an output filter of the DC-DC converter;
measuring a voltage at the first node; and
calculating values for parameters of the output filter based on the voltage.

18. The method of claim 17, wherein calculating the values comprises calculating an effective series inductance.

19. The method of claim 17, wherein calculating the values comprises calculating an effective series resistance.

20. The method of claim 17, wherein calculating the values comprises calculating a capacitance.

21. A mobile communication device comprising a power management die comprising:
a direct current (DC)-to-DC (DC-DC) converter configured to output a signal for an amplifier chain at a first node corresponding to an input of an output filter;
a control circuit configured to initiate a calibration process and turn off the DC-DC converter during the calibration process; and
a calibration circuit comprising:
a current source configured to provide a known current to the first node during the calibration process;
a measurement circuit coupled to the first node configured to measure a voltage at the first node during the calibration process; and
a control circuit configured to calculate values associated with the output filter and use those values to control, in part, the DC-DC converter.
